(19) United States
(12) Patent Application Publication
(10) Pub. No.: US 2025/0391686 A1
(43) Pub. Date: Dec. 25, 2025

(54) APPARATUS FOR DETECTING CRACK IN SEMICONDUCTOR CHIP

(71) Applicant: SK hynix Inc., Gyeonggi-do (KR)

(72) Inventors: Jong Su KIM, Gyeonggi-do (KR); Sun Joo PARK, Gyeonggi-do (KR)

(21) Appl. No.: 19/308,332

(22) Filed: Aug. 25, 2025

Related U.S. Application Data
(62) Division of application No. 17/589,021, filed on Jan. 31, 2022.

(30) Foreign Application Priority Data
Aug. 20, 2021 (KR) 10-2021-0110535

(51) Int. Cl. H01L 21/67; G01N 21/95; G01N 23/2251; G01N 29/06; H01L 21/68; H01L 21/78

(52) U.S. Cl. CPC H01L 21/67288; G01N 21/9505; G01N 23/2251; G01N 29/0654; H01L 21/681; H01L 21/78; G01N 2223/07; G01N 2223/102; G01N 2223/403; G01N 2223/6116

(57) ABSTRACT

An apparatus for detecting a crack of a semiconductor chip may include a crack sensor including a charging pattern disposed on a first surface of a target layer in which cracks are to be detected, a charge sinking pattern disposed on a second surface of the target layer, and a connecting pattern that electrically connects the charging pattern to the charge sinking pattern. The apparatus for detecting a crack may further include a charger for charging electric charges to the charging pattern, an image detector for obtaining an image of the charging pattern, and a determination unit that detects a discolored charging pattern from the image of the charging pattern and determines that a crack has occurred in a portion of the target layer in which the discolored charging pattern is located.

### CROSS-REFERENCE TO RELATED APPLICATIONS

The present application is a division of U.S. patent application Ser. No. 17/589,021 filed on Jan. 31, 2022, which claims priority under 35 U.S.C 119(a) to Korean Patent Application No. 10-2021-0110535, filed on Aug. 20, 2021, which is incorporated herein by reference in its entirety.

### BACKGROUND

### 1. Technical Field

The present disclosure generally relates to a semiconductor technology and, more particularly, to an apparatus for detecting a crack in a semiconductor chip.

### 2. Related Art

Integrated circuits (ICs) may be repeatedly formed on a wafer, and the wafer may be separated into individual semiconductor chips. The wafer may be diced or cut into multiple semiconductor chips. The semiconductor chips separated from the wafer may be packaged into semiconductor packages. During a process of separating the wafer into semiconductor chips or a process of packaging the semiconductor chips, a crack may be generated in the semiconductor chip. There is a demand for detecting cracks generated in semiconductor chips.

### SUMMARY

An apparatus for detecting a crack according to an embodiment of the present disclosure includes a target layer; charging patterns disposed on a first surface of the target layer; a charge sinking pattern disposed on a second surface opposite to the first surface of the target layer; connecting patterns electrically connecting the charging patterns to the charge sinking pattern; a charger for charging electric charges to the charging patterns; an image detector for obtaining images of the charging patterns in which the electric charges are charged; and a determination unit that detects a color change in at least one of the charging pattern from the images of the charging patterns and determines that a crack has occurred in a portion of the target layer in which the charging pattern with the detected color change is located.

An apparatus for detecting a crack according to another embodiment of the present disclosure includes a semiconductor substrate including a chip region and a scribe lane region; a target layer disposed on the semiconductor substrate; charging patterns disposed on a first surface of the target layer; connecting patterns electrically connecting the charging patterns to the scribe lane region of the semiconductor substrate; a charger for charging electric charges to the charging patterns; an image detector for obtaining images of the charging patterns in which the electric charges are charged; and a determination unit that detects color change in at least one of the charging pattern from the images of the charging patterns and determines that a crack has occurred in a portion of the target layer in which the charging pattern with the color change is located.

An apparatus for detecting a crack according to another embodiment of the present disclosure includes a semiconductor substrate including a chip region and a scribe lane region; an insulation layer disposed on the semiconductor substrate; a target layer disposed on the insulation layer; charging patterns disposed on a first surface of the target layer and positioned over the scribe lane region; a charge sinking pattern disposed on a second surface opposite to the first surface of the target layer; connecting patterns electrically connecting the charging patterns to the charge sinking pattern; a charger for charging electric charges to the charging patterns; an image detector for obtaining images of the charging patterns in which the electric charges are charged; and a determination unit that detects a color change of at least one of the charging pattern from the images of the charging patterns and determines that a crack has occurred in a portion of the target layer in which the charging pattern with the color change is located.

### BRIEF DESCRIPTION OF THE DRAWINGS

FIG. 1 is a schematic view illustrating an apparatus for detecting a crack according to an embodiment of the present disclosure.

FIG. 2 is a schematic plan view illustrating a planar shape in which crack sensor groups of the apparatus for detecting a crack of FIG. 1 are disposed.

FIG. 3 is a schematic plan view illustrating an X-Y plane shape in which crack sensors of the apparatus for detecting a crack of FIG. 1 are disposed.

FIGS. 4 to 7 are schematic views illustrating a crack detection by the apparatus for detecting a crack of FIG. 1.

FIG. 8 is a schematic cross-sectional view illustrating a crack sensor of an apparatus for detecting a crack according to another embodiment of the present disclosure.

FIG. 9 is a schematic cross-sectional view illustrating a crack sensor of an apparatus for detecting a crack according to another embodiment of the present disclosure.

FIG. 10 is a schematic plan view illustrating a crack sensor of an apparatus for detecting a crack according to another embodiment of the present disclosure.

FIG. 11 is a schematic cross-sectional view illustrating a crack sensor of an apparatus for detecting a crack according to another embodiment of the present disclosure.

FIG. 12 is a block diagram illustrating an electronic system employing a memory card including a package according to an embodiment of the present disclosure.

FIG. 13 is a block diagram illustrating an electronic system including a package according to an embodiment of the present disclosure.

### DETAILED DESCRIPTION

Unless otherwise defined, the terms (including technical and scientific terms) used herein have the same meaning as commonly understood by one of ordinary skill in the art to which the embodiments belong.

It will be understood that although the terms “first” and “second,” “side,” “top,” and “bottom or lower” may be used herein to describe various elements, these elements should not be limited by these terms. These terms are only used to distinguish one element from another element, but not used to indicate a particular sequence or number of elements.

The semiconductor device may include a semiconductor substrate or a structure in which a plurality of semiconductor substrates are stacked. The semiconductor device may refer to a semiconductor package structure in which a structure in which semiconductor substrates are stacked is packaged. The semiconductor substrate may refer to a semiconductor wafer, a semiconductor die, or a semiconductor chip in which electronic components and devices are integrated. The semiconductor chip may refer to a memory chip in which memory integrated circuits such as dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits, or phase change random access memory (PcRAM) are integrated, logic dies or ASIC chips in which logic circuits are integrated in a semiconductor substrate, or processors such as application processors (APs), graphic processing units (GPUs), central processing units (CPUs) or system-on-chips (SoCs). The semiconductor device may be employed in information communication systems such as mobile phones, electronic systems associated with biotechnology or health care, or wearable electronic systems. The semiconductor device may be applicable to internet of things (IoT).

Same reference numerals refer to same elements throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

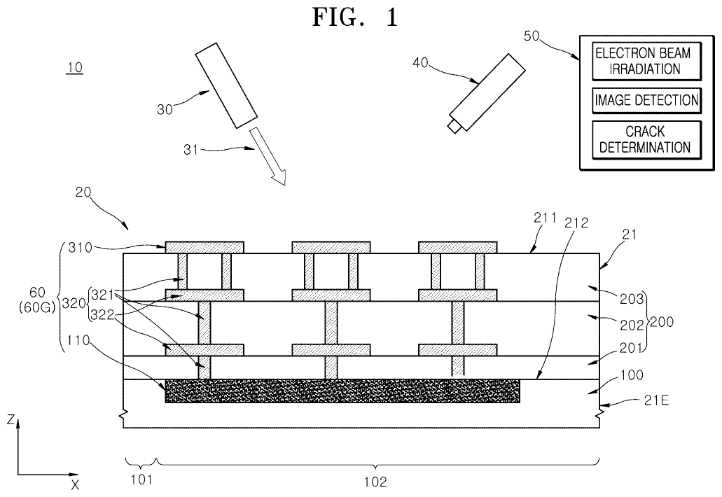

FIG. 1 is a schematic view illustrating an apparatus 10 for detecting a crack according to an embodiment of the present disclosure. In addition, FIG. 1 illustrate an X-Z cross-sectional shape of a semiconductor chip 20 of the apparatus 10 for detecting a crack.

Referring to FIG. 1, the apparatus 10 for detecting a crack may be configured to detect a crack that can be generated in the semiconductor chip 20. The apparatus 10 may include the semiconductor chip 20, a charger 30, an image detector 40, and a determination unit 50. The semiconductor chip 20 may include a target layer 200 and crack sensors 60. The charger 30 may include an electron gun. The charger 30 may irradiate electrons or an electron beam 31 to surfaces of the crack sensors 60 to substantially charge the crack sensors 60. The image detector 40 may obtain an image of surface shapes of the crack sensors 60. The image detector 40 may include a Scanning Electron Microscope (SEM). The image detector 40 may obtain an SEM image to the surface of the crack sensors 60. The determination unit 50 may control the electron beam irradiation operation of the charger 30, control the image detection operation of the image detector 40, and determine whether a crack has been generated based on the obtained image.

When a crack is generated in the semiconductor chip 20, the crack may damage the crack sensors 60. When the charger 30 charges the crack sensors 60 in a state in which the crack sensors 60 are damaged by the crack, the charging states of the crack sensors 60 may be changed from that of the undamaged normal state. The image detector 40 may detect a change in the charging state of the crack sensors 60 as an image, and the determination unit 50 may determine whether a crack occurs using the detected image.

The semiconductor chip 20 may include a semiconductor substrate 100, the target layer 200, and the crack sensors 60. The semiconductor substrate 100 may include chip regions 101 and a scribe lane region 102. The chip regions 101 may be partial regions of the semiconductor substrate 100 in which integrated circuits are integrated. The scribe lane region 102 may be another region of the semiconductor substrate 100 adjacent to a side that is a dividing surface 21 of the semiconductor chip 20. The scribe lane region 102 may include regions between the chip regions 101 and the dividing surface 21 of the semiconductor chip 20. The semiconductor substrate 100 may include a semiconductor material such as silicon (Si). The semiconductor substrate 100 may be a substrate doped with a p-type dopant such as boron (B).

The semiconductor chip 20 may further include the target layer 200 stacked on the semiconductor substrate 100. The target layer 200 may include a structure in which a plurality of dielectric layers are stacked. The target layer 200 may include a first dielectric layer 201, a second dielectric layer 202, and a third dielectric layer 203. The target layer 200 may include a larger number of dielectric layers or a smaller number of dielectric layers.

The semiconductor chip may further include the crack sensors 60. The crack sensors 60 may be disposed to be positioned over the scribe lane region 102 of the semiconductor substrate 100. Because the crack sensors 60 are not disposed over the chip regions 101 but are disposed over the scribe lane region 102, the crack sensors 60 may detect cracks occurring in the scribe lane region 102. The crack sensors 60 may be configured to substantially penetrate the target layer 200, and thus may detect the cracks generated in the target layer 200. The crack sensors 60 may be configured to be substantially connected to or in electrical contact with the semiconductor substrate 100. The crack sensors 60 may detect the cracks generated at an interface between the target layer 200 and the semiconductor substrate 100. In the present disclosure, the crack may indicate a broken portion occurring inside the target layer 200 or may indicate delamination of the target layer 200 from the semiconductor substate 100. The crack may indicate delamination of sub-layers of the target layer 200.

Each of the crack sensors 60 may include a charging pattern 310, a charge sinking pattern 110, and connecting patterns 320. A plurality of crack sensors 60 may be gathered to form a crack sensor group 60G, and may be disposed in the semiconductor chip 20.

The charging patterns 310 may be disposed on a first surface 211 of the target layer 200. The charging patterns 310 may be disposed on the first surface 211 of the target layer 200 to be positioned over the scribe lane region 102 of the semiconductor substrate 100. The first surface 211 of the target layer 200 may be an upper surface of the semiconductor chip 20, so that the charging patterns 310 are exposed to an external environment of the semiconductor chip 20. Accordingly, it is possible to detect images of the charging patterns 310 by the image detector 40. An SEM image of the charging patterns 310 may be obtained by the SEM of the image detector 40. The charging patterns 310 may include metal patterns. In the obtained SEM image, the metal patterns may have changed color when charged with electric charges such as electrons. When the charging patterns 310 are charged with electrons or electric charges, the charging patterns 310 of the SEM image may be discolored to a color different from that in an uncharged state or that in a discharged state. The charging patterns 310 may be metal patterns including metal such as aluminum (Al) or copper (Cu).

In the SEM image, one of the charging patterns 310 in which electrons are charged may exhibits a color different from the colors of the others of the charging patterns 310 in which electrons are discharged. SEM of the image detector 40 detects secondary electrons that are generated when primary electrons collide with the charging patterns 310 and takes magnified images of the charging patterns 310. The number of secondary electrons emitted or generated from the charging patterns 310 may vary depending on states in which the charging patterns 310 are charged. One of the charging patterns 310 in which electrons are charged may emit a relatively smaller number of secondary electrons than that of the others of the charging patterns 310 in which electrons are not charged. Accordingly, one of the charging patterns 310 in which electrons are charged may exhibit a color darker than that of the other of the charging patterns 310 in which electrons are not charged and discharged.

The charge sinking pattern 110 may be disposed on a second surface 212 of the target layer 200. The second surface 212 of the target layer 200 may be a surface opposite to the first surface 211. The second surface 212 of the target layer 200 may be the lower surface of the target layer 200 which interfaces with the substrate 100. The charge sinking pattern 110 may include a metal pattern. The charge sinking pattern 110 may include a conductive material such as polycrystalline silicon. The charge sinking pattern 110 may be a portion of the semiconductor substrate 100. The charge sinking pattern 110 may be formed as a region doped with a dopant in the semiconductor substrate 100. The charge sinking pattern 110 may include a region doped with an n-type dopant in the semiconductor substrate 100. The charge sinking pattern 110 may include a conductive well formed by doping the semiconductor substrate 100 with a dopant. An upper portion of the semiconductor substrate 100 may be doped with an n-type dopant such as arsenic (As) or phosphorus (P) to form an N-well, and the N-well may be configured as the charge sinking pattern 110.

The connecting patterns 320 may be formed as conductive structures substantially penetrating the target layer 200. The connecting patterns 320 may electrically connect the charging patterns 310 and the charge sinking pattern 110 to each other. Electrons or electric charges charged in the charging patterns 310 may move to the charge sinking pattern 110 through the connecting patterns 320. Through the connecting patterns 320, the electrons or electric charges charged in the charging patterns 310 may escape to the charge sinking pattern 110. Accordingly, the electrons or electric charges charged in the charging patterns 310 may be erased or discharged by the connecting patterns 320 and the charge sinking pattern 110.

The connecting patterns 320 may be disposed in the target layer 200 to be positioned over the scribed lane region 102 of the semiconductor substrate 100. The connecting patterns 320 may be disposed between the dividing surface 21 of the semiconductor chip 20 and the chip region 101. The connecting patterns 320 may be disposed between an edge 21E of the semiconductor substrate 100 that is a portion of the dividing surface 21 of the semiconductor chip 20 and the chip region 101. The charging patterns 310 connected to the connecting patterns 320 may be disposed between the edge 21E of the semiconductor substrate 100 and the chip region 101.

Each of the connecting patterns 320 may be formed of various conductive materials. The connecting patterns 320 may include metal patterns or conductive polycrystalline silicon patterns. The connecting patterns 320 may include conductive contacts 321 substantially penetrating the target layer 200. The conductive contacts 321 may be formed to penetrate the dielectric layers 201, 202, and 203 constituting the target layer 200. The connecting patterns 320 may further include conductive lands 322 positioned at the interfaces of the dielectric layers 201, 202, and 203, and the conductive contacts 321 may be connected to the conductive lands 322. The conductive lands 322 may include metal patterns or conductive polycrystalline silicon patterns. Some of the conductive lands 322 may be formed of metal patterns, and other of the conductive lands 322 may be formed of conductive polycrystalline silicon patterns. Each of the conductive contacts 321 may be extending in the direction of the stacking of the first, second, and third dielectric layers of the target layer 200 (i.e., the Z direction) while the conductive lands 322 may extend in the direction parallel to an upper surface of the substrate 100 (i.e., the X direction).

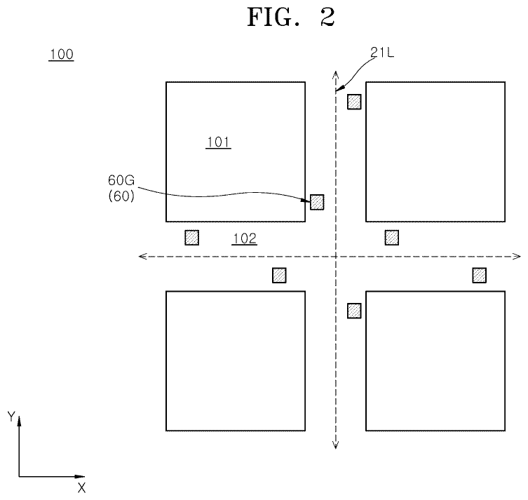

FIG. 2 is a schematic plan view illustrating an X-Y plane shape in which the crack sensor groups 60G of the apparatus 10 for detecting a crack of FIG. 1 are disposed.

Referring to FIG. 2, the crack sensor groups 60G including the plurality of crack sensors 60 may be disposed over the scribe lane region 102 of the semiconductor substrate 100. The semiconductor substrate 100 may include a plurality of repeatedly disposed chip regions 101, and the scribe lane region 102 may be disposed between the chip regions 101. By removing portions of the scribe lane region 102, the semiconductor substrate 100 may be divided into semiconductor chips 20 of FIG. 1, each including the chip region 101. The semiconductor substrate 100 may be divided along a dividing line 21L set in the scribe lane region 102. The process of dividing the semiconductor substrate 100 may be performed by a sawing process using a blade, a laser dividing process using a laser, or a stealth dicing process.

In the process of dividing the semiconductor substrate 100 along the dividing line 21L, cracks may be generated in the semiconductor chip 20 or the scribe lane region 102 of the semiconductor substrate 100. In order to detect the cracks, the crack sensors 60 or the crack sensor groups 60G may be dispersed throughout the scribe lane region 102 along the boundaries of the chip regions 101.

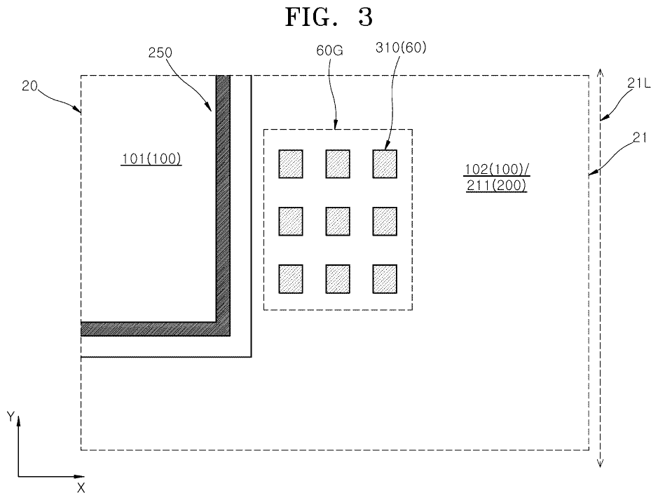

FIG. 3 is a schematic plan view illustrating an X-Y plane shape in which the crack sensors 60 of the apparatus 10 for detecting a crack of FIG. 1 are disposed.

Referring to FIG. 3, the crack sensor group 60G may include the plurality of crack sensors 60. The charging patterns 310 may be disposed in a plurality of matrices on the first surface 211 of the target layer 200, corresponding to the scribe lane region 102. The charging patterns 310 or the crack sensors 60 may be arranged in a plurality of columns between the chip regions 101 and the dividing surface 21 of the semiconductor chip 20. A plurality of the charging patterns 310 or crack sensors 60 may be arranged in the X-axis direction, and a plurality of the charging patterns 310 or crack sensors 60 may be arranged in the Y-axis direction.

A sealing guard 250 that prevents moisture from penetrating into the circuits integrated in the chip region 101 of the semiconductor chip 20 may be formed. The sealing guard 250 may be formed in a pattern extending along the boundary of the chip region 101 to form a ring shape. The plurality of charging patterns 310 or crack sensors 60 may be disposed between the sealing guard 250 and the dividing surface 21 of the semiconductor chip 20.

In the process of dividing the semiconductor substrate 100 along the dividing line 21L, cracks may be generated in the semiconductor chip 20 or the scribe lane region 102 of the semiconductor substrate 100. The cracks may be generated in various layers constituting the semiconductor chip 20. Moisture may be introduced into the semiconductor chip 20 through the cracks. As moisture flows into the semiconductor chip 20, the circuits integrated in the semiconductor chip 20 may malfunction due to the moisture. As such, the crack may act as a factor for lowering the yield of the semiconductor chip 20. Accordingly, it may be required to check to what extent the crack extends toward the chip region 101 from the dividing line 21L or the dividing plane 21 divided along the dividing line 21L. The plurality of charging patterns 310 or crack sensors 60 are disposed between the chip region 101 and the dividing surface 21 of the semiconductor chip 20, so that it is possible to check to what extent the crack extends from the dividing face 21 toward the chip region 101.

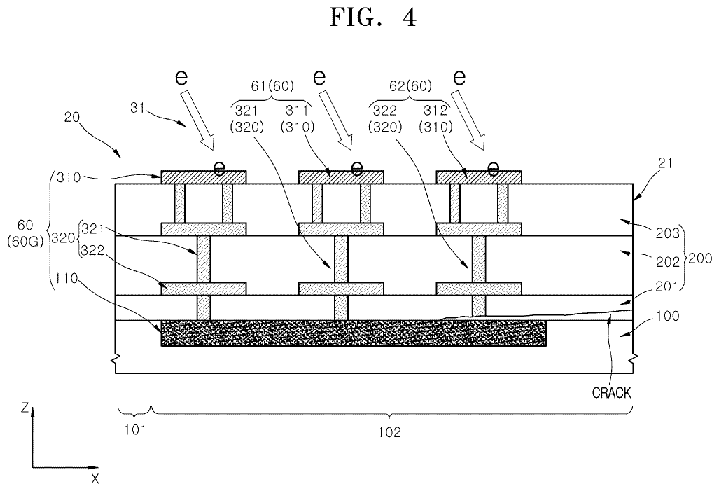

FIGS. 4 to 7 are schematic views illustrating a crack detection by the apparatus 10 for detecting a crack of FIG. 1.

Referring to FIG. 4 together with FIG. 1, the charger 30 may irradiate electrons or an electron beam 31 to the charging patterns 310 of the crack sensors 60 to charge electrons or electric charges to the charging patterns 310. As electrons or electric charges are charged to the charging patterns 310, the charging patterns 310 may be discolored to a second color different from a first color in an uncharged state in SEM image.

A first connecting pattern 321 of a first crack sensor 61 may electrically connect a first charging pattern 311 to the charge sinking pattern 110. A second connecting pattern 322 of a second crack sensor 62 may be in a broken state by cracks that may be generated while dividing the dividing surface 21. The second connecting pattern 322 may be damaged by the cracks and might not be able to connect the second charging pattern 312 to the charge sinking pattern 110. Accordingly, the behavior of the electrons or electric charges charged in the first charging pattern 311 and the second charging pattern 312 may be different.

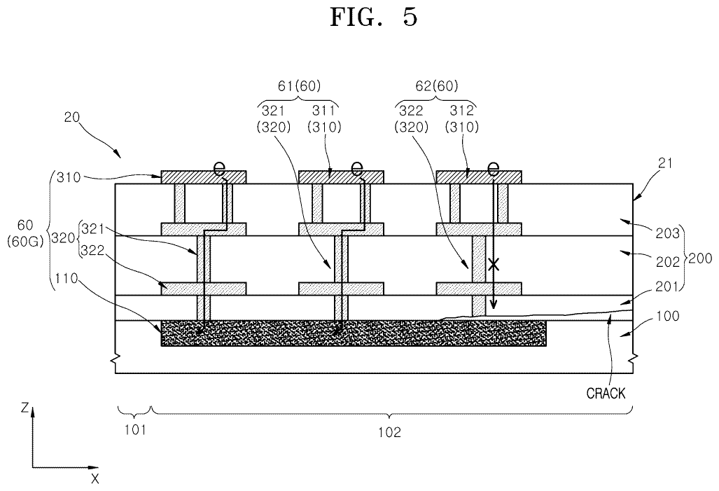

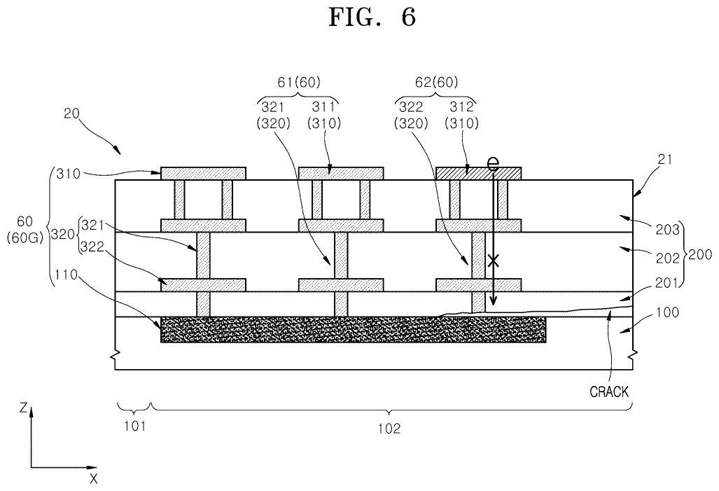

Referring to FIGS. 5 and 6, the electrons or electric charges charged in the first charging pattern 311 may escape to the charge sinking pattern 110 through the first connecting pattern 321 and be erased. Accordingly, the first charging pattern 311 may be converted from a charged state as shown in FIG. 5 to a state in which charged charges or electrons are erased as shown in FIG. 6. Accordingly, the first charging pattern 311 may change color from the second color in the charged state as shown in FIG. 5 to the first color in the uncharged state as shown in FIG. 6.

Referring to FIGS. 5 and 6, because the second connecting pattern 322 is disconnected from the charge sinking pattern 110 by the crack, the electrons or electric charges charged in the second charging pattern 312 might not escape to the charge sinking pattern 110. Accordingly, the second charging pattern 312 may be maintained in a state in which electrons or electric charges are charged. Accordingly, the second charging pattern 312 may be maintained in the charged state as shown in FIGS. 5 and 6. The second charging pattern 312 may maintain the second color of the charged state as shown in FIGS. 5 and 6.

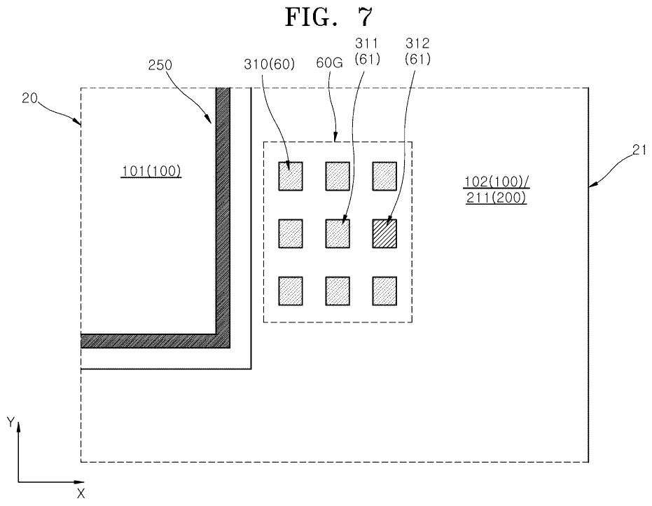

After charging electrons or electric charges to the first and second charging patterns 311 and 312, images of the charged first and second charging patterns 311 and 312 may be obtained through the image detector 40 in FIG. 1. As shown in FIG. 7, the images of the first and second charging patterns 311 and 312 may show that the second charging pattern 312 has the second color different from that of the first charging pattern 311 or those of other charging patterns 310. The discolored second charging pattern 312 may be detected from the images of the charging patterns 310 and it may be determined that the crack of FIG. 6 is generated in the portion of the target layer 200 where the discolored second charging pattern 312 is located.

As described above, the apparatus for detecting a crack according to an embodiment of the present disclosure detects whether the charging patterns 310 of the crack sensors 60 maintain a charged state or whether the charged electrons are erased by the charge sinking pattern 110 and the charging patterns 310 are in an erased state, so that it is possible to identify whether cracks have occurred through the images. In addition, by disposing a plurality of crack sensors 60, it is possible to detect positions where cracks have been generated.

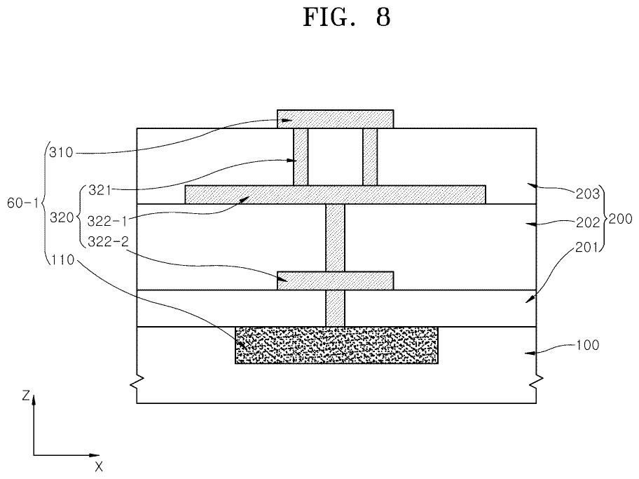

FIG. 8 is a schematic cross-sectional view illustrating a crack sensor 60-1 according to another embodiment of the present disclosure. In FIG. 8, elements indicated by the same reference numerals as in FIG. 1 or depicted in the same shape may be understood as substantially identical elements.

Referring to FIGS. 8 and 1, the apparatus 10 for detecting a crack may include the crack sensor 60-1 according to another embodiment of the present disclosure. The crack sensor 60-1 may include a charging pattern 310, a charge sinking pattern 110, and connecting patterns 320. A target layer 200 may include a first dielectric layer 201, a second dielectric layer 202, and a third dielectric layer 203.

The connecting patterns 320 may include conductive contacts 321. The conductive contacts 321 may be formed to penetrate the dielectric layers 201, 202, and 203 constituting the target layer 200. The connecting patterns 320 may further include a first conductive land 322-1 and a second conductive land 322-2 positioned at interfaces between the dielectric layers 201, 202, and 203, and the conductive contacts 321 may be connected to the first conductive land 322-1 and the second conductive land 322-2. The first conductive land 322-1 may be positioned at the interface between the second dielectric layer 202 and the third dielectric layer 203, and may be connected to the charging pattern 310 through the conductive contacts 321. The first conductive land 322-1 may include a metal pattern having a wider width or a larger area and a larger volume than the charging pattern 310. Accordingly, the electrons or electric charges charged in the charging pattern 310 may escape to the first conductive land 322-1 at a higher speed.

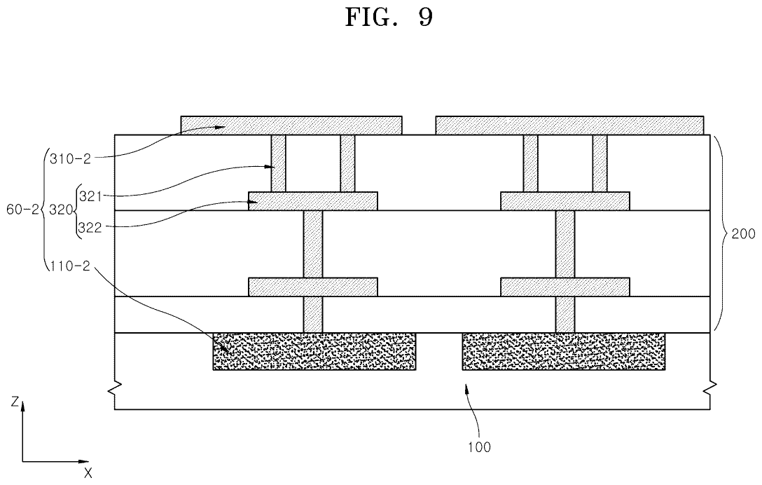

FIG. 9 is a schematic cross-sectional view illustrating crack sensors 60-2 according to another embodiment of the present disclosure. In FIG. 9, elements indicated by the same reference numerals as in FIG. 1 or depicted in the same shape may be understood as substantially identical elements.

Referring to FIGS. 9 and 1, the apparatus 10 for detecting a crack may include the crack sensors 60-2 according to another embodiment of the present disclosure. The crack sensors 60-2 may include charging patterns 310-2, charge sinking patterns 110-2, and connecting patterns 320. The charge sinking patterns 110-2 may include conductive wells separated from each other to which the connecting patterns 320 are respectively connected. The semiconductor substrate 100 and the conductive wells may be doped with dopants of opposite conductivity types. The semiconductor substrate 100 may be doped with a p-type dopant, and the conductive well may be doped with an N-well. Each of the charging patterns 310-2 may be formed in a pattern having a wider width or a larger area than a conductive land 322 of the connecting pattern 320. Because the charging patterns 310-2 are formed in patterns having a large area, a greater number of electrons or charges may be charged. Accordingly, the discoloration of the charging patterns 310-2 may be more easily identified.

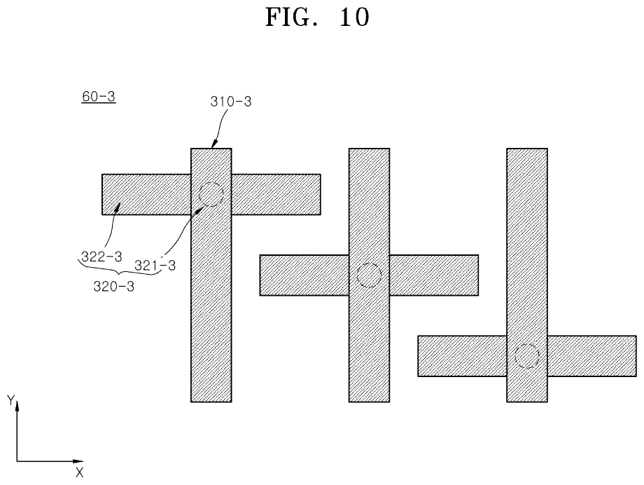

FIG. 10 is a schematic plan view illustrating crack sensors 60-3 according to another embodiment of the present disclosure. In FIG. 10, elements indicated by the same reference numerals as in FIG. 1 or depicted in the same shape may be understood as substantially identical elements.

Referring to FIGS. 10 and 1, an apparatus 10 for detecting a crack may include the crack sensors 60-3 according to another embodiment of the present disclosure. The crack sensors 60-3 may include charging patterns 310-3 and connecting patterns 320-3. Each of the connecting patterns 320-3 may include a conductive land 322-3 and a conductive contact 321-3. The conductive land 322-3 may include a metal pattern orthogonal to the charging pattern 310-3 when viewed in a vertical direction. The conductive lands 322-3 and the charging pattern 310-3 are formed of metal patterns that are orthogonal to each other, the conductive lands 322-3 and the charging patterns 310-3 may be formed as patterns having a larger area within a limited area.

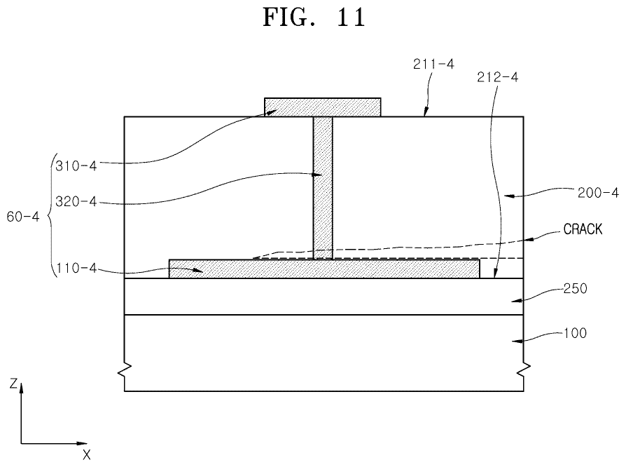

FIG. 11 is a schematic cross-sectional view illustrating a crack sensor 60-4 according to another embodiment of the present disclosure. In FIG. 11, elements indicated by the same reference numerals as in FIG. 1 or depicted in the same shape may be understood as substantially identical elements.

Referring to FIGS. 11 and 1, an apparatus 10 for detecting a crack may include the crack sensor 60-4 according to another embodiment of the present disclosure. The crack sensor 60-4 may include a charging pattern 310-4, a connecting pattern 320-4, and a charge sinking pattern 110-4. The charging pattern 310-4 may be disposed including a metal pattern on a first surface 211-4 of a target layer 200-4. The charge sinking pattern 110-4 may be disposed on a second surface 212-4 of the target layer 200-4. The charge sinking pattern 110-4 may be electrically separated from a semiconductor substrate 100 by an underlying insulation layer 250. The charge sinking pattern 110-4 may be electrically insulated by the insulation layer 250 and the target layer 200-4, and may be electrically connected to the charging pattern 310-4 by the connecting pattern 320-4. The connecting pattern 320-4 may include a conductive contact.

The electrons or electric charges charged in the charging pattern 310-4 may move to the charge sinking pattern 110-4 through the connecting pattern 320-4 and accumulate in the charge sinking pattern 110-4. Accordingly, the charging pattern 310-4 may be converted from a charged state to a state in which the electrons or electric charges are erased. When the connecting pattern 320-4 is broken by a crack and the connection between the charging pattern 310-4 and the charge sinking pattern 110-4 is cut, the charging pattern 310-4 may be maintained in a charged state. The charge sinking pattern 110-4 may include a metal pattern having a wider width or a larger area and a larger volume than the charging pattern 310-4. Accordingly, the amount of electrons or electric charges that can be accumulated in the charge sinking pattern 110-4 may increase, so that the electrons or electric charges may be more smoothly discharged into the charge sinking pattern 110-4. Similar to the conductive land 322-3 of FIG. 10, the charge sinking pattern 110-4 may be formed in a metal pattern orthogonal to the charging pattern 310-4.

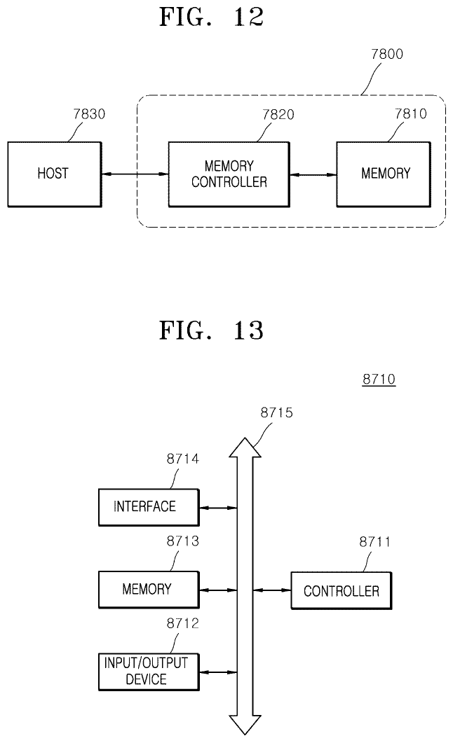

FIG. 12 is a block diagram illustrating an electronic system including a memory card 7800 employing at least one of the semiconductor packages according to the embodiments. The memory card 7800 includes a memory 7810 such as a nonvolatile memory device, and a memory controller 7820. The memory 7810 and the memory controller 7820 may store data or read out the stored data. At least one of the memory 7810 and the memory controller 7820 may include at least one of the semiconductor packages according to the embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

FIG. 13 is a block diagram illustrating an electronic system 8710 including at least one of the semiconductor packages according to the embodiments. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include at least one of the semiconductor packages according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system using a technique of, for example, CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or WiBro (wireless broadband Internet).

The inventive concept has been disclosed in conjunction with embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all of distinctive features in the equivalent scope should be construed as being included in the inventive concept.

What is claimed is:

1. An article comprising:
a semiconductor chip, wherein the semiconductor chip includes:
a semiconductor substrate including a chip region and a scribe lane region;
a target layer disposed on the semiconductor substrate;
charging patterns disposed on a first surface of the target layer;
a charge sinking pattern disposed underneath the charging patterns; and
connecting patterns electrically connecting the charging patterns to the charge sinking pattern in the scribe lane region of the semiconductor substrate,
wherein a crack is detected in the scribe region by monitoring images of the charging patterns,
wherein the crack has occurred in a portion of the target layer in which an image of one of the charging patterns differs over time from the images from other of the charging patterns,
wherein the images of the charging patterns are obtained by an image detector from the charging patterns in which the electric charges are charged, and
wherein the charging patterns are electrically charged by a charger.

2. The article of claim 1, wherein the charging patterns are positioned over the scribe lane region of the semiconductor substrate.

3. The article of claim 1, wherein the charging patterns are disposed between an edge and the chip region of the semiconductor substrate.

4. The article of claim 1, wherein the image detector includes scanning electron microscope to obtain the images of the charging patterns.

5. The article of claim 1, wherein the electric charges charged to the charging patterns move to the semiconductor substrate through the connecting patterns, and
the charge sinking pattern which receives the electric charges has a larger area and a larger volume than an area and a volume of each of the charging patterns, and includes a metal pattern orthogonal to the charging pattern.

6. The article of claim 5, wherein the semiconductor substrate includes conductive wells separated from each other and to which the connecting patterns are respectively connected.

7. The article of claim 6, wherein the semiconductor substrate and the conductive wells are doped with dopants of opposite conductivity types.
